(19) United States
(12) Patent Application Publication
(10) Pub. No.: US 2011/0156539 A1
(43) Pub. Date: Jun. 30, 2011

(54) PIEZOELECTRIC ACTUATOR FOR ACTUATING HAPTIC DEVICE

(76) Inventors: Dong Sun PARK, Seoul (KR); Yeon Ho Son, Gyunggi-do (KR); Jae Kyung Kim, Gyunggi-do (KR); Ki Suk Woo, Seoul (KR); Dae Woong Yun, Incheno (KR); Kum Kyung Lee, Gyunggi-do (KR); Su Young Jung, Gyunggi-do (KR); Ji Yeoun Jang, Gyunggi-do (KR)

(21) Appl. No.: 12/716,177

(22) Filed: Mar. 2, 2010

(30) Foreign Application Priority Data
Dec. 30, 2009 (KR) 10-2009-0134269

(51) Int. Cl. H01L 41/047

(52) U.S. Cl. 310/366

(57) ABSTRACT

Disclosed herein is a piezoelectric actuator for actuating a haptic device, which includes a piezoelectric element having a plurality of piezoelectric layers which are stacked and have the same polling direction, and an electrode pattern formed on the piezoelectric element, in which the length of each of the plurality of piezoelectric layers is greater than or equal to four times the width of each of the plurality of piezoelectric layers, and the width of each of the plurality of piezoelectric layers is greater than or equal to ten times the thickness of each of the plurality of piezoelectric layers, so that the piezoelectric actuator can greatly vibrate in the direction of length with reduced power consumption.

### CROSS REFERENCE TO RELATED APPLICATION

This application claims the benefit of Korean Patent Application No. 10-2009-0134269, filed Dec. 30, 2009, entitled “Piezoelectric actuator actuating haptic device”, which is hereby incorporated by reference in its entirety into this application.

### BACKGROUND OF THE INVENTION

1. Technical Field

The present invention relates to a piezoelectric actuator for actuating a haptic device.

2. Description of the Related Art

A variety of methods are devised to allow a user to more easily and conveniently communicate with a computer or program. Recently, haptic devices having the concept of reflecting the intuitive experience of a user in an interface and further diversifying feedback in addition to the concept of being touched and input by a user are mainly employed.

The haptic device is advantageous because it enables space saving, improves and simplifies its manipulation, makes its design change simple, ensures high user recognition, and is easy to connect with IT devices. Hence, the haptic device having the above advantages is being widely utilized in fields including industry, traffic, service, medical care, mobile and so on.

Generally, a haptic device is configured such that, in the case where a user presses a transparent touch panel thereof which is closely attached to an imaging device for displaying an image such as an LCD in conjunction with viewing the image via the touch panel, the sense of vibration is applied to the touch panel by means of a vibration generator such as a vibration motor or a piezoelectric actuator, and is then transferred to the user.

As such, however, the vibration generator, in particular, the vibration motor is operated so as to apply tactile feedback to the user based on a manner of causing the entire mobile phone to vibrate, undesirably reducing the sense of vibration which is transferred to the user via the touch panel. On the other hand, the piezoelectric actuator is mainly used these days because it causes a predetermined portion of the device to vibrate thus improving the sense of vibration.

FIG. 1 is a perspective view showing a piezoelectric actuator for actuating a haptic device according to a conventional technique, and FIG. 2 is a cross-sectional view showing the piezoelectric actuator of FIG. 1. Below, the piezoelectric actuator 10 according to the conventional technique is described.

As shown in FIGS. 1 and 2, the piezoelectric actuator 10 includes a piezoelectric element 11 having a plurality of piezoelectric layers 11a, 11b, 11c which are stacked, inner electrodes 12 formed between the plurality of piezoelectric layers 11a, 11b, 11c, and outer electrodes 13 formed on the outer surface of the piezoelectric element 11.

When user input is transferred to the piezoelectric actuator 10, power applied to the outer electrodes 13 is transmitted to the inner electrodes 12, thus expanding and contracting the piezoelectric element 11, thereby generating vibration.

However, the conventional piezoelectric actuator 10 is problematic because the polling directions are not set to be the same as each other, and thus the piezoelectric actuator 10 unexpectedly vibrates not in the direction of the length l but in the direction of the thickness t.

Furthermore, as the haptic device becomes slim, the piezoelectric layers 11a, 11b, 11c of the piezoelectric actuator 10 are formed thinner, whereby the value C of the piezoelectric layers 11a, 11b, 11c is enlarged, undesirably increasing power consumption. In particular, because the haptic device such as a portable device is limited in terms of battery capacity, its problem becomes more serious.

### SUMMARY OF THE INVENTION

Accordingly, the present invention has been made keeping in mind the problems encountered in the related art and the present invention is intended to provide a piezoelectric actuator for actuating a haptic device, in which polling directions are set to be the same as each other so that the piezoelectric actuator vibrates in the direction of its length.

Also the present invention is intended to provide a piezoelectric actuator for actuating a haptic device, in which a piezoelectric layer is designed to be at least a predetermined thickness so that the value C of the piezoelectric layer is lowered and power consumption is reduced.

An aspect of the present invention provides a piezoelectric actuator for actuating a haptic device, including a piezoelectric element including a plurality of piezoelectric layers which are stacked and have the same polling direction, and an electrode pattern formed on the piezoelectric element, wherein the length of each of the plurality of piezoelectric layers is greater than or equal to four times the width of each of the plurality of piezoelectric layers, and the width of each of the plurality of piezoelectric layers is greater than or equal to ten times the thickness of each of the plurality of piezoelectric layers.

In this aspect, the electrode pattern may include a first electrode including a first inner electrode provided inside the piezoelectric element and a first outer electrode formed on one side of the outer surface of the piezoelectric element and connected to the first inner electrode, and a second electrode including a second inner electrode provided inside the piezoelectric element and a second outer electrode formed on the other side of the outer surface of the piezoelectric element and connected to the second inner electrode.

In this aspect, the piezoelectric element may expand and contract in the direction of the length.

In this aspect, each of the plurality of piezoelectric layers may have a hexahedral shape.

In this aspect, each of the plurality of piezoelectric layers may have a thickness of 50˜150 μm.

### BRIEF DESCRIPTION OF THE DRAWINGS

The features and advantages of the present invention will be more clearly understood from the following detailed description taken in conjunction with the accompanying drawings, in which:

FIG. 1 is a perspective view showing a piezoelectric actuator for actuating a haptic device according to a conventional technique;

FIG. 2 is a cross-sectional view showing the piezoelectric actuator of FIG. 1;

FIG. 3 is a perspective view showing a piezoelectric actuator for actuating a haptic device according to an embodiment of the present invention;

FIG. 4 is a cross-sectional view showing the piezoelectric actuator of FIG. 3;

FIGS. 5 and 6 are graphs showing the amplitude of the piezoelectric actuator according to the embodiment of the present invention depending on the length, width and thickness of piezoelectric layers; and

FIGS. 7 and 8 are views showing the principle of actuating the piezoelectric actuator of FIG. 3.

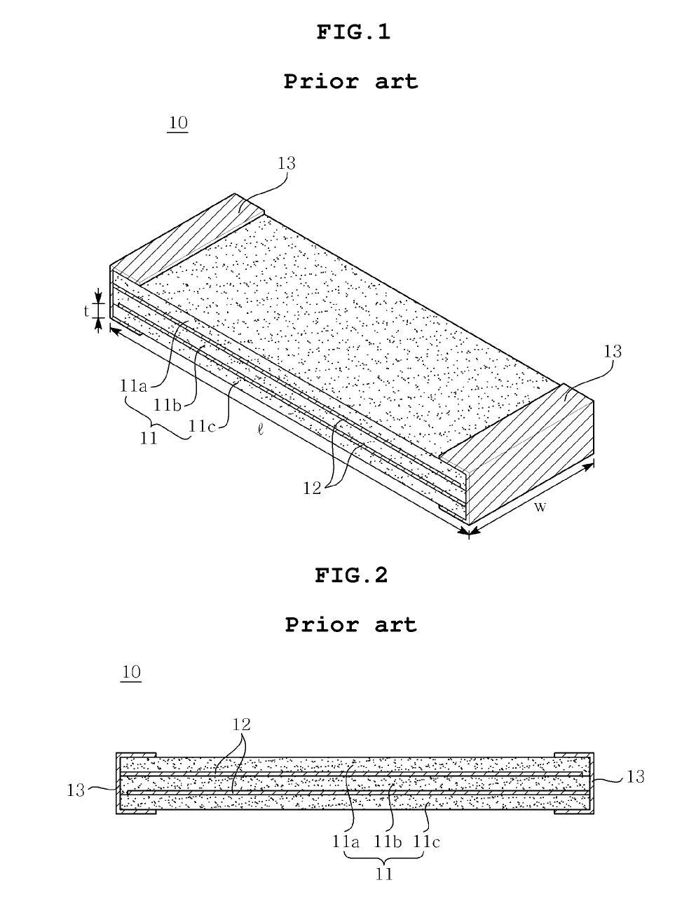

### DESCRIPTION OF SPECIFIC EMBODIMENTS

Hereinafter, embodiments of the present invention will be described in detail while referring to the accompanying drawings. Throughout the drawings, the same reference numerals are used to refer to the same or similar elements. In the description, the terms “first”, “second” and so on are used to distinguish one element from another element, and the elements are not defined by the above terms. Moreover, descriptions of known techniques, even if they are pertinent to the present invention, are regarded as unnecessary and may be omitted when they would make the characteristics of the invention and the description unclear.

Furthermore, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention.

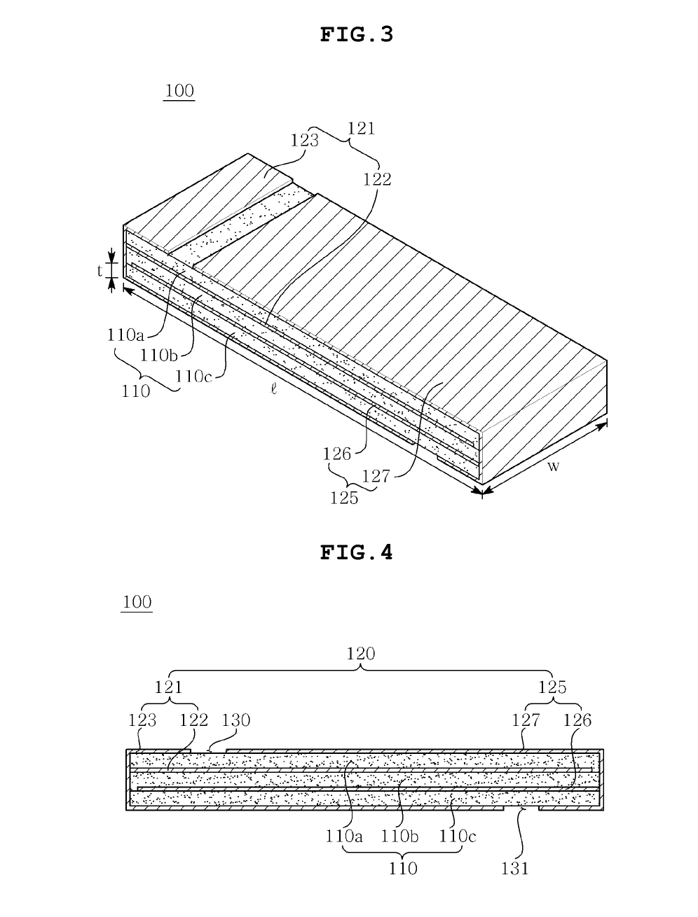

FIG. 3 is a perspective view showing a piezoelectric actuator for actuating a haptic device according to an embodiment of the present invention, and FIG. 4 is a cross-sectional view showing the piezoelectric actuator of FIG. 3. With reference to these drawings, the piezoelectric actuator 100 for actuating a haptic device according to the present embodiment is described below.

As shown in FIGS. 3 and 4, the piezoelectric actuator 100 for actuating a haptic device according to the present embodiment includes a piezoelectric element 110 and an electrode pattern 120. The piezoelectric element 110 includes a plurality of piezoelectric layers 110a, 110b, 110c, in which the polling directions of the plurality of piezoelectric layers 110a, 110b, 110c are the same as each other, and the width w, length l and thickness t of respective piezoelectric layers 110a, 110b, 110c are related to the actuation of the piezoelectric actuator 100.

The piezoelectric element 110 generates vibrations (vibration mode) by stress when power is applied, and includes the plurality of piezoelectric layers 110a, 110b, 110c, which are stacked. The piezoelectric layers 110a, 110b, 110c are formed of a piezoelectric ceramic sheet, for example, lead zirconate titanate (PZT), and may thus expand and contract in a predetermined direction when power is applied to the electrode pattern 120 which will be specified later.

In order to enhance the vibration generating force, the polling directions of the plurality of piezoelectric layers 110a, 110b, 110c may be set to be the same as each other. When the plurality of piezoelectric layers 110a, 110b, 110c have the same polling direction, the potential is decreased but the vibration generating force may be enhanced and also the piezoelectric actuator may vibrate in the direction of length l. In contrast, when the polling directions of the plurality of piezoelectric layers 110a, 110b, 110c are different from each other, the potential is increased but the vibration generating force is reduced, and also the piezoelectric actuator vibrates in the direction of thickness t, and thus the vibration mode itself may change. As such, in the haptic device not the potential but the vibration force recognized by the tactile sense of a user plays a more important role, and thus the polling directions should be set to be the same as each other. Because the piezoelectric element 110 includes the plurality of piezoelectric layers 110a, 110b, 110c having the same polling direction, it may be expand and contract in the direction of length l when power is applied to the electrode pattern 120.

In FIGS. 3 and 4, three piezoelectric layers 110a, 110b, 110c are illustratively shown, and the piezoelectric layers 110a, 110b, 110c may be provided in the form of a single layer or a multilayer.

Furthermore, the piezoelectric element 110 may have a hexahedral shape, and may be formed in the directions of length l, width w, and thickness t, as shown in FIG. 3.

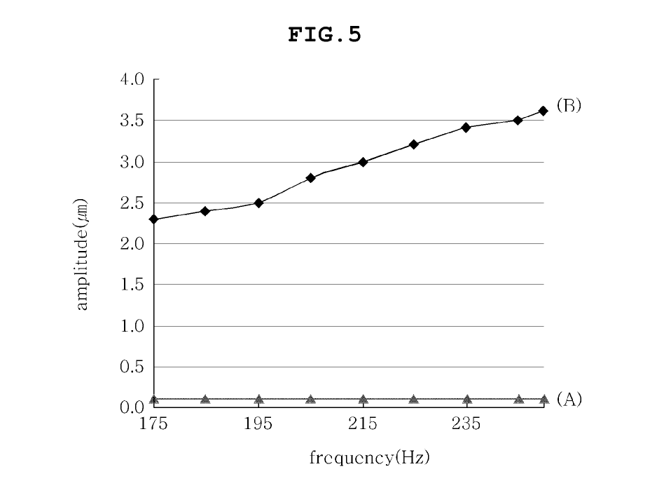

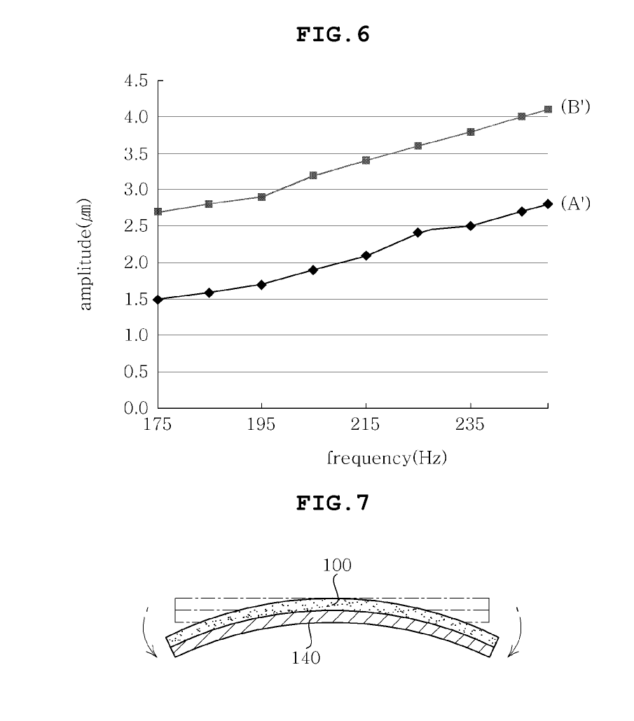

In order to maximize the vibration of respective piezoelectric layers 110a, 110b, 110c in the direction of length l, respective piezoelectric layers 110a, 110b, 110c should have length l, width w, and thickness t satisfying a ratio of length l≧4×width w≧40×thickness t. When the ratio of length l of the hexahedral piezoelectric element 110 is set in this way, the piezoelectric actuator 100 represents a vibration mode which expands and contracts in the direction of length l, and the vibration generating force may be maximized, which is specified later with reference to FIGS. 5 and 6.

As the thickness of respective piezoelectric layers 110a, 110b, 110c is decreased, the value C is enlarged, and also, as the value C is enlarged, current and power consumption are increased. Thus, respective piezoelectric layers 110a, 110b, 110c should be designed such that the thickness thereof is maintained to at least a predetermined level to thus decrease the value C. When the thickness of respective piezoelectric layers 110a, 110b, 110c is maintained to at least 50 μm, power consumption may be reduced.

In the case where respective piezoelectric layers 110a, 110b, 110c become excessively thicker, the total thickness of the haptic device is increased and the stacking process becomes problematic. So, the upper limit of the thickness of the piezoelectric layers may be set to 150 μm or less.

The electrode pattern 120 includes a first electrode 121 and a second electrode 125, and may be formed using for example a silver (Ag) paste. The electrode pattern 120 functions to transmit power to the inside of the piezoelectric element 110 from an external substrate (not shown).

As such, the first electrode 121 includes a first inner electrode 122 and a first outer electrode 123. The first inner electrode 122 may be disposed between for example the first piezoelectric layer 110a and the second piezoelectric layer 110b, and may be connected to the first outer electrode 123 formed on one side of the outer surface of the piezoelectric element 110. In addition, the second electrode 125 may include a second inner electrode 126 and a second outer electrode 127. The second inner electrode 126 may be formed between for example the second piezoelectric layer 110b and the third piezoelectric layer 110c and may be connected to the second outer electrode 127 formed on the other side of the outer surface of the piezoelectric element 110.

In order to prevent the first electrode 121 from shorting out with the second electrode 125, the first inner electrode 122 may be spaced apart from the second outer electrode 127, and the second inner electrode 126 may be spaced apart from the first outer electrode 123. Also, in order to maximize the vibration force, the first outer electrode 123 and the second outer electrode 127 may be formed on the outer surface of the piezoelectric element 110 in areas other than the upper space 130 and the lower space 131.

When power is applied to the piezoelectric actuator 100, it is transmitted to the first inner electrode 122 and the second inner electrode 126 from the first outer electrode 123 and the second outer electrode 127, respectively.

FIGS. 5 and 6 are graphs showing the amplitude of the piezoelectric actuator 100 according to the present embodiment depending on the length l, width w and thickness t of the piezoelectric layers 110a, 110b, 110c, which is described below.

In FIG. 5, the graph (B) shows the amplitude of the piezoelectric actuator 100 when the length l, width w, and thickness t of the piezoelectric actuator 100 are respectively 15 mm, 2 mm and 0.1 mm, and the graph (A) shows the amplitude of the piezoelectric actuator 100 when the length l, width w, and thickness t thereof are respectively 2 mm, 2 mm and 0.1 mm As shown in FIG. 5, the graph (B) satisfying the ratio of length l≧4×width w≧40×thickness t can be seen to have the amplitude greater than that of the graph (A) not satisfying the ratio of length l≧4×width w≧40×thickness t, regardless of the frequency.

In FIG. 6, the graph (B′) shows the amplitude of the piezoelectric actuator 100 when the length l, width w, and thickness t of the piezoelectric actuator 100 are respectively 20 mm, 2 mm and 0.1 mm, and the graph (A′) shows the amplitude of the piezoelectric actuator 100 when the length l, width w, and thickness t thereof are respectively 20 mm, 0.5 mm and 0.1 mm As shown in FIG. 6, the graph (B′) satisfying the ratio of length l≧4×width w≧40×thickness t can be seen to have the amplitude greater than that of the graph (A′) not satisfying the ratio of length l≧4×width w≧40×thickness t, regardless of the frequency. Therefore, when respective piezoelectric layers 110a, 110b, 110c satisfy the ratio of length l≧4×width w≧40×thickness t, the amplitude may be remarkably increased regardless of the frequency, and thus the vibration force may be enhanced.

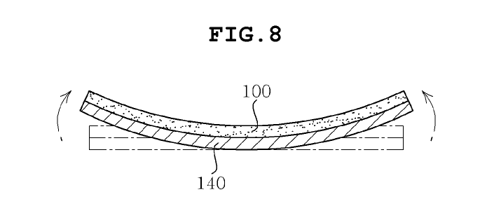

FIGS. 7 and 8 show the principle of actuating the piezoelectric actuator 100 of FIG. 3, which is described below.

In the drawings, a plate 140 functions to provide a space for mounting the piezoelectric actuator 100 on a haptic device and to transfer vibration from the piezoelectric actuator 100 to for example a touch panel (not shown) or an imaging element (not shown), and may be attached to the touch panel (not shown) or the imaging element (not shown). In the present embodiment, the piezoelectric actuator 100 may be provided in the form of being attached to the plate 140 of the haptic device, but the present invention is not limited thereto.

As shown in FIGS. 7 and 8, when power is applied to the electrode pattern 120 of the piezoelectric actuator 100, the first outer electrode 123 and the second outer electrode 127 respectively transfer current to the first inner electrode 122 and the second outer electrode 127, so that the piezoelectric element 110 may expand and contract.

When the length of the piezoelectric element 110 is increased by the applied power, the piezoelectric actuator 100, which is attached to the plate 140 having a comparatively small strain, may warp downward (FIG. 7). In contrast, when the length of the piezoelectric element 110 is decreased, the piezoelectric actuator 100 may warp upward (FIG. 8).

Thereby, the user of the haptic device having the piezoelectric actuator 100 may sense the vibration feedback because of the upward or downward vibration as above.

As described hereinbefore, the present invention provides a piezoelectric actuator for actuating a haptic device. According to the present invention, the polling directions of the piezoelectric actuator are set to be the same as each other, thus enabling the piezoelectric actuator to be actuated in the direction of length and resulting in a large vibration generating force.

Also, according to the present invention, piezoelectric layers are formed such that the length thereof is greater than or equal to four times the width thereof and the width thereof is greater than or equal to ten times the thickness thereof, thus maximizing the vibration force and enabling the piezoelectric actuator to be actuated in the direction of length.

Also, according to the present invention, respective piezoelectric layers are designed to have a thickness ranging from 50 μm to 150 μm, thus reducing power consumption, coping with slimness of the haptic device, and making it easy for process control.

Although the embodiments of the present invention regarding the piezoelectric actuator for actuating a haptic device have been disclosed for illustrative purposes, those skilled in the art will appreciate that a variety of different modifications, additions and substitutions are possible, without departing from the scope and spirit of the invention as disclosed in the accompanying claims. Accordingly, such modifications, additions and substitutions should also be understood as falling within the scope of the present invention.

1. A piezoelectric actuator for actuating a haptic device, comprising:
a piezoelectric element comprising a plurality of piezoelectric layers which are stacked and have a same polling direction; and
an electrode pattern formed on the piezoelectric element,
wherein a length of each of the plurality of piezoelectric layers is greater than or equal to four times a width of each of the plurality of piezoelectric layers, and the width of each of the plurality of piezoelectric layers is greater than or equal to ten times a thickness of each of the plurality of piezoelectric layers,
the electrode pattern comprises a plurality of inner electrodes provided inside the piezoelectric element and a plurality of outer electrodes formed on an outer surface of the piezoelectric element and connected to each of the plurality of inner electrodes, and
a piezoelectric element having upper space and lower space which are formed by separating the plurality of outer electrodes, the plurality of outer electrodes formed on the outer surface of the piezoelectric element in areas other than the upper space and the lower space.

2. The piezoelectric actuator as set forth in claim 1, wherein the electrode pattern comprises:
a first electrode comprising a first inner electrode provided inside the piezoelectric element and a first outer electrode formed on one side of an outer surface of the piezoelectric element and connected to the first inner electrode; and
a second electrode comprising a second inner electrode provided inside the piezoelectric element and a second outer electrode formed on the other side of the outer surface of the piezoelectric element and connected to the second inner electrode.

3. The piezoelectric actuator as set forth in claim 1, wherein the piezoelectric element expands and contracts in a direction of length.

4. The piezoelectric actuator as set forth in claim 1, wherein each of the plurality of piezoelectric layers has a hexahedral shape.

5. The piezoelectric actuator as set forth in claim 1, wherein each of the plurality of piezoelectric layers has a thickness of 50˜150 μm.
